(19) United States
(12) Patent Application Publication
(10) Pub. No.: US 2007/0130491 A1
(43) Pub. Date: Jun. 7, 2007

(54) Error detection of digital logic circuits using hierarchical neural networks

(76) Inventor: Didarul Alam Mazumder, Austin, TX (US)

Correspondence Address: DUKE W. YEE;YEE & ASSOCIATES, P.C., P.O. BOX 802333, DALLAS, TX, 75380, US

(21) Appl. No.: 11/295,298

(22) Filed: Dec. 6, 2005

(51) Int. Cl. G06F 11/00; G01R 31/28

(52) U.S. Cl. 714/735; 714/736

(57) ABSTRACT

An artificial neural network for detecting and identifying errors in digital circuits is provided. Data from digital circuits are received and organized into current data set patterns by a supervisory control and data acquisition system. The supervisory control and data acquisition system transmits the current data set patterns to an artificial neural network error detection module. The artificial neural network error detection module compares the actual output of each current data set pattern to a calculated output for a corresponding stored data set pattern. The artificial neural network error detection module determines whether a match condition exists for the comparison. The artificial neural network error detection module outputs the results of the determination to a user interface.

### BACKGROUND OF THE INVENTION

1. Field of the Invention

The present invention relates generally to a method, system and computer program product for detecting and identifying errors in digital circuits. More specifically, the present invention relates to artificial neural networks for detecting and identifying errors in digital circuits.

2. Description of the Related Art

In the integrated circuit industry today, millions of semiconductor devices are built on a single chip. The current demands for high density and performance associated with ultra large scale integration require submicron features, increased transistor and circuit speeds and improved reliability. Every device on the chip must be electrically isolated to ensure that it operates independently without interfering with another.

Noise margin, soft error, flipping the logic, manufacturing error, wrong gate-type, and extra/missing inverters, etc. can cause errors in any digital circuit. In many cases, detecting the specific error is not possible or is very difficult. Current methods for detecting errors include debugging and synthesizing multilevel circuits. However, often these methods do not yield correct results when detecting errors in digital logic circuits and identifying which circuit is the source of the error.

### SUMMARY OF THE INVENTION

The present invention provides a method, system, and computer program product for detecting and identifying errors in digital circuits. A plurality of inputs are received and organized into a plurality of current data set patterns. The actual output of each current data set pattern is compared to a calculated output of a corresponding stored data set pattern. A determination is made as to whether a match condition exists.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 is a pictorial representation of a network of data processing systems in which exemplary aspects of the present invention may be implemented;

FIG. 2 is a block diagram of a data processing system in which exemplary aspects of the present invention may be implemented;

FIG. 3 is a block diagram illustrating a system for error detection in digital logic circuits, in accordance with an exemplary embodiment of the present invention;

FIG. 4 is a block diagram depicting a section of a typical digital logic circuit in accordance with an exemplary embodiment of the present invention;

FIG. 5 is a block diagram illustrating an exemplary embodiment of an artificial neural network (ANN) in accordance with an exemplary embodiment of the present invention;

FIG. 6 is a table illustrating the corresponding inputs and outputs of the ANN sub-modules of FIG. 5, in accordance with an exemplary embodiment of the present invention;

FIG. 7 is a block diagram of a multiperceptron network, in accordance with an exemplary embodiment of the present invention; and

FIG. 8 is a flowchart illustrating the operation of detecting and identifying errors in accordance with an exemplary embodiment of the present invention.

### DETAILED DESCRIPTION OF THE PREFERRED EMBODIMENT

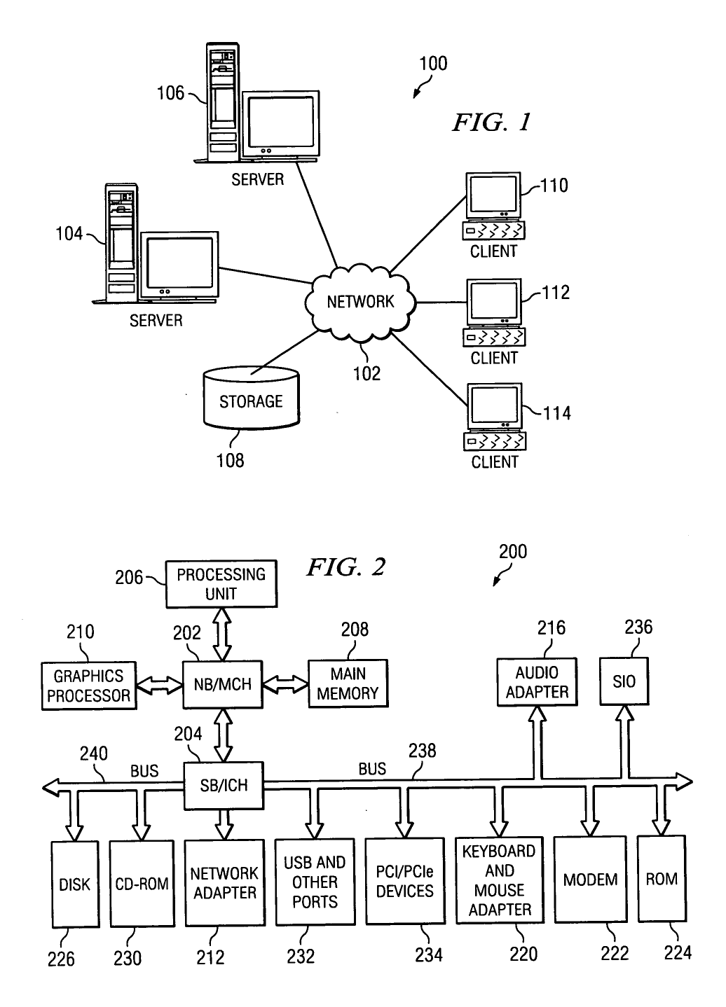

FIGS. 1-2 are provided as exemplary diagrams of data processing environments in which embodiments of the present invention may be implemented. It should be appreciated that FIGS. 1-2 are only exemplary and are not intended to assert or imply any limitation with regard to the environments in which aspects or embodiments of the present invention may be implemented. Many modifications to the depicted environments may be made without departing from the spirit and scope of the present invention.

With reference now to the figures, FIG. 1 depicts a pictorial representation of a network of data processing systems in which aspects of the present invention may be implemented. Network data processing system 100 is a network of computers in which embodiments of the present invention may be implemented. Network data processing system 100 contains network 102, which is the medium used to provide communications links between various devices and computers connected together within network data processing system 100. Network 102 may include connections, such as wire, wireless communication links, or fiber optic cables.

In the depicted example, server 104 and server 106 connect to network 102 along with storage unit 108. In addition, clients 110, 112, and 114 connect to network 102. These clients 110, 112, and 114 may be, for example, personal computers or network computers. In the depicted example, server 104 provides data, such as boot files, operating system images, and applications to clients 110, 112, and 114. Clients 110, 112, and 114 are clients to server 104 in this example. Network data processing system 100 may include additional servers, clients, and other devices not shown.

In the depicted example, network data processing system 100 is the Internet with network 102 representing a worldwide collection of networks and gateways that use the Transmission Control Protocol/Internet Protocol (TCP/IP) suite of protocols to communicate with one another. At the heart of the Internet is a backbone of high-speed data communication lines between major nodes or host computers, consisting of thousands of commercial, government, educational and other computer systems that route data and messages. Of course, network data processing system 100 also may be implemented as a number of different types of networks, such as for example, an intranet, a local area network (LAN), or a wide area network (WAN). FIG. 1 is intended as an example, and not as an architectural limitation for different embodiments of the present invention.

With reference now to FIG. 2, a block diagram of a data processing system is shown in which aspects of the present invention may be implemented. Data processing system 200 is an example of a computer, such as server 104 or client 110 in FIG. 1, in which computer usable code or instructions implementing the processes for embodiments of the present invention may be located.

In the depicted example, data processing system 200 employs a hub architecture including north bridge and memory controller hub (MCH) 202 and south bridge and input/output (I/O) controller hub (ICH) 204. Processing unit 206, main memory 208, and graphics processor 210 are connected to north bridge and memory controller hub 202. Graphics processor 210 may be connected to north bridge and memory controller hub 202 through an accelerated graphics port (AGP).

In the depicted example, local area network (LAN) adapter 212 connects to south bridge and I/O controller hub 204. Audio adapter 216, keyboard and mouse adapter 220, modem 222, read only memory (ROM) 224, hard disk drive (HDD) 226, CD-ROM drive 230, universal serial bus (USB) ports and other communications ports 232, and PCI/PCIe devices 234 connect to south bridge and I/O controller hub 204 through bus 238 and bus 240. PCI/PCIe devices may include, for example, Ethernet adapters, add-in cards and PC cards for notebook computers. PCI uses a card bus controller, while PCIe does not. ROM 224 may be, for example, a flash binary input/output system (BIOS).

Hard disk drive 226 and CD-ROM drive 230 connect to south bridge and I/O controller hub 204 through bus 240. Hard disk drive 226 and CD-ROM drive 230 may use, for example, an integrated drive electronics (IDE) or serial advanced technology attachment (SATA) interface. Super I/O (SIO) device 236 may be connected to south bridge and I/O controller hub 204.

An operating system runs on processing unit 206 and coordinates and provides control of various components within data processing system 200 in FIG. 2. As a client, the operating system may be a commercially available operating system such as Microsoft® Windows® XP (Microsoft and Windows are trademarks of Microsoft Corporation in the United States, other countries, or both). An object-oriented programming system, such as the Java™ programming system, may run in conjunction with the operating system and provides calls to the operating system from Java programs or applications executing on data processing system 200 (Java is a trademark of Sun Microsystems, Inc. in the United States, other countries, or both).

As a server, data processing system 200 may be, for example, an IBM eServer™ pSeries® computer system, running the Advanced Interactive Executive (AIX®) operating system or LINUX operating system (eServer, pSeries and AIX are trademarks of International Business Machines Corporation in the United States, other countries, or both while Linux is a trademark of Linus Torvalds in the United States, other countries, or both). Data processing system 200 may be a symmetric multiprocessor (SMP) system including a plurality of processors in processing unit 206. Alternatively, a single processor system may be employed.

Instructions for the operating system, the object-oriented programming system, and applications or programs are located on storage devices, such as hard disk drive 226, and may be loaded into main memory 208 for execution by processing unit 206. The processes for embodiments of the present invention are performed by processing unit 206 using computer usable program code, which may be located in a memory such as, for example, main memory 208, read only memory 224, or in one or more peripheral devices 226 and 230.

Those of ordinary skill in the art will appreciate that the hardware in FIGS. 1-2 may vary depending on the implementation. Other internal hardware or peripheral devices, such as flash memory, equivalent non-volatile memory, or optical disk drives and the like, may be used in addition to or in place of the hardware depicted in FIGS. 1-2. Also, the processes of the present invention may be applied to a multiprocessor data processing system.

In some illustrative examples, data processing system 200 may be a personal digital assistant (PDA), which is configured with flash memory to provide non-volatile memory for storing operating system files and/or user-generated data.

A bus system may be comprised of one or more buses, such as bus 238 or bus 240 as shown in FIG. 2. of course the bus system may be implemented using any type of communications fabric or architecture that provides for a transfer of data between different components or devices attached to the fabric or architecture. A communications unit may include one or more devices used to transmit and receive data, such as modem 222 or network adapter 212 of FIG. 2. A memory may be, for example, main memory 208, read only memory 224, or a cache such as found in north bridge and memory controller hub 202 in FIG. 2. The depicted examples in FIGS. 1-2 and above-described examples are not meant to imply architectural limitations. For example, data processing system 200 also may be a tablet computer, laptop computer, or telephone device in addition to taking the form of a PDA.

Detecting errors in digital logic circuits and identifying which circuit is the source of the error is a difficult task. In an exemplary embodiment, the present invention detects errors in digital logic circuits and identifies which circuit is the source of the error. Any error in a digital logic circuit may be detected by a hierarchical and/or artificial neural network (ANN) provided in an exemplary embodiment of the present invention. The ANN compares the output of the data received to the calculated output of a stored data set and determines if a match condition exists. If the received data matches the expected data, then no error has occurred. In an exemplary embodiment, the ANN outputs its results in binary, a 1 meaning an error has occurred, a zero indicating no error occurred.

A match condition exists if either the calculated output and actual output are exactly the same value or the calculated output and actual output are nearly the same value. The reason for the variance is that in training an ANN some variance will arise in the results over the course of training. Therefore, the output of anyone gate may not be 1 or 0 100% of the time. However, as explained in FIG. 8, the ANN is trained until the variance is less than 0.001. Thus, a match can occur if the actual output and the calculated output for any logic element are within 0.001 or less of each other.

In another exemplary embodiment, the user can perform and view error detection through a user friendly interactive interface. The present invention is easy to implement. The user interface allows anyone to use the present invention without any programming knowledge. Knowledge of hierarchical artificial neural networks is also not necessary to implement exemplary embodiments of the present invention. Exemplary embodiments of the present invention return robust and immediate results to the user.

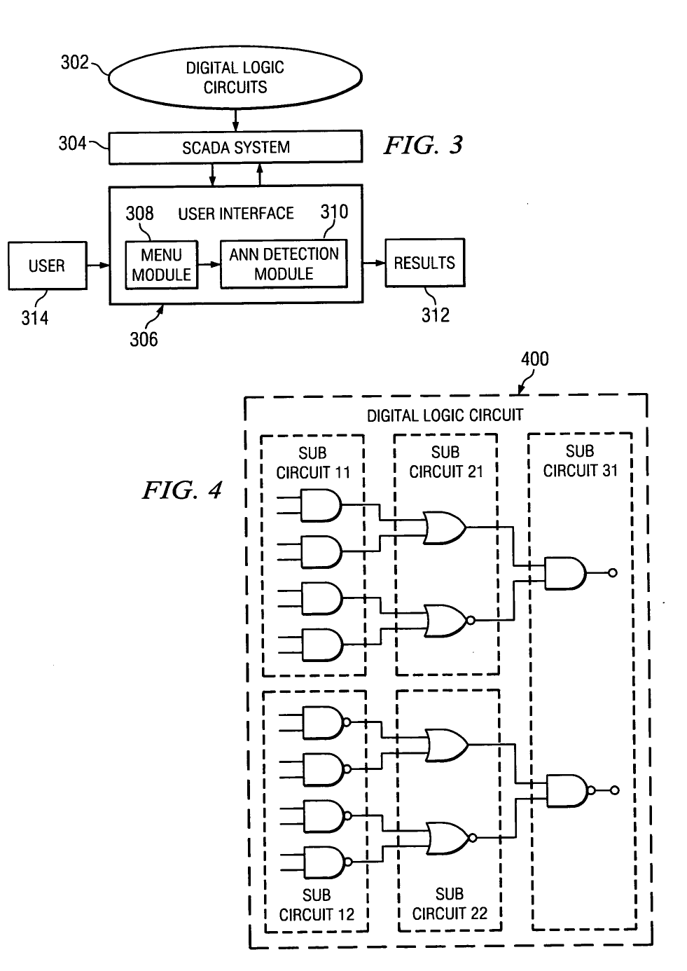

In an exemplary embodiment of the present invention, error detection modules are implemented in a user-friendly manner in a computer based environment in which menus are provided for the user's convenience. Depending on the system implementation, the error detection modules may be implemented in a real-time environment. An exemplary embodiment of the present invention comprises various modules, as illustrated in FIG. 3.

FIG. 3 is a block diagram illustrating a system for error detection in digital logic circuits, in accordance with an exemplary embodiment of the present invention. The error detection system comprises several components including digital logic circuits 302, supervisory control and data acquisition (SCADA) system 304, and user interface 306. SCADA system 304 comprises a programmable logic device and associated software. User interface 306 comprises menu module 308 and ANN detection module 310. Menu module 308 allows user 314 to control and direct the error detection process and view results 312 thereof.

Digital logic circuits 302 may be any type of digital logic circuits including AND, OR, NAND, NOR, XOR, XNOR, Inverter etc. Digital logic circuits 302 is connected to SCADA system 304. Digital logic circuits 302 generates data in a digital form and sends the data to SCADA system 304. SCADA system 304 generates data set patterns and sends the patterns to ANN detection module 310 of user interface 306. ANN detection module 310 performs error detection and displays results 312 to user 314. The specific circuit which generated the error may also be identified and displayed as part of results 312.

FIG. 4 is a block diagram depicting a section of a typical digital logic circuit in accordance with an exemplary embodiment of the present invention. Digital logic circuit 400, which may be implemented as digital logic circuit 302 in FIG. 3, comprises five sub-circuits, 11, 12, 21, 22 and 31. Sub-circuit 11 feeds into sub-circuit 21. Sub-circuit 12 feeds into sub-circuit 22. Sub-circuit 21 feeds into sub-circuit 31. Sub-circuit 22 feeds into sub-circuit 31.

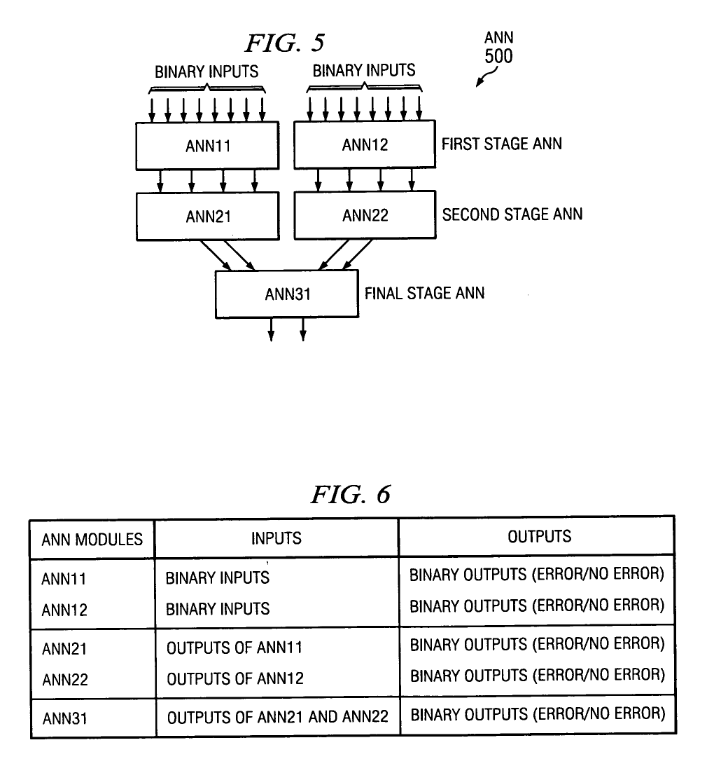

FIG. 5 is a block diagram illustrating an exemplary embodiment of an ANN in accordance with an exemplary embodiment of the present invention. The ANN depicted in FIG. 5, ANN 500, which may be implemented as ANN detection module 310 in FIG. 3, has been designed to test digital logic circuit 400, as depicted in FIG. 4 to determine whether an error has occurred. Those skilled in the art will realize that for simple circuits, a one stage ANN may be sufficient to detect the occurrence of errors while a hierarchical ANN may be used for larger and/or more complex circuits.

ANN 500 comprises a three stage hierarchical ANN. These three hierarchical modules are referred to as ANN1, ANN2 and ANN3. Module ANN1 is the first stage ANN. Module ANN1 is further divided into two sub-modules, ANN11 and ANN12. Sub-modules ANN11 and ANN12 detect the occurrence of errors in the first stage gates of digital logic circuit 400, as depicted in FIG. 4. Specifically, sub-module ANN11 checks sub-circuit 11 and sub-module ANN12 checks sub-circuit 12. Sub-module ANN11 receives binary input and outputs binary for sub-module ANN21. Sub-module ANN12 receives binary input and outputs binary for sub-module ANN22.

Module ANN2 is the second stage ANN. Module ANN2 also comprises two sub-modules, ANN21, and ANN22. Sub-modules ANN21, and ANN22 detect the occurrence of errors in the second stage gates of digital logic circuit 400, as depicted in FIG. 4. Specifically, sub-module ANN21 checks sub-circuit 21 and sub-module ANN22 checks sub-circuit 22. Sub-module ANN21 receives sub-module ANN11's binary output and outputs binary for sub-module ANN31. Sub-module ANN22 receives sub-module ANN12's binary output and outputs binary for sub-module ANN31.

Module ANN3 is the third stage ANN. Module ANN3 comprises one sub-module ANN31. Sub-module ANN31 detects the occurrence of errors in the third stage gates of digital logic circuit 400, as depicted in FIG. 4. Sub-module ANN31 receives sub-modules ANN21 and ANN22's binary output and outputs binary.

FIG. 6 is a table illustrating the corresponding inputs and outputs of the ANN sub-modules of FIG. 5, in accordance with an exemplary embodiment of the present invention. In the first stage of the hierarchical ANN, ANN1 of FIG. 5, which comprises sub-modules ANN11 and ANN12, the inputs of the ANN1 are the binary inputs and their corresponding outputs are binary outputs. The binary outputs indicate whether an error occurred. These binary outputs may be displayed to a user through a user interface, such as user interface 306 in FIG. 3. Thus, the user can easily tell which logic gates in the first stage are producing the error.

In the second stage of hierarchical ANN, ANN2 of FIG. 5, which comprises sub-modules ANN21 and ANN22, the inputs are the outputs of sub-modules ANN11 and ANN12. The outputs of ANN2 are binary outputs. The binary outputs indicate whether an error occurred. These binary outputs may be displayed to a user through a user interface, such as user interface 306 in FIG. 3. Thus, the user can easily tell which logic gates in the second stage are producing the error.

In the third stage of hierarchical ANN, ANN3 of FIG. 5, which comprises sub-module ANN31, the inputs are the outputs of sub-modules ANN21 and ANN22. The outputs of ANN31 are binary outputs. The binary outputs indicate whether an error occurred. These binary outputs may be displayed to a user through a user interface, such as user interface 306 in FIG. 3. Thus, the user can easily tell which logic gates in the second stage are producing the error.

FIGS. 4-6 describe an exemplary embodiment of a hierarchical ANN comprising three levels with two sub-modules included in each of the first two levels. However, it would be obvious to one skilled in the art that the particular structure and composition of the ANN would vary with the particular implementation. An ANN could comprise any number of levels and any level may be comprised of any number of sub-modules.

The description of the exemplary embodiment of the present invention has been presented for purposes of illustration and description, and is not intended to be exhaustive or limited to the invention in the form disclosed. Many modifications and variations will be apparent to those of ordinary skill in the art. The exemplary embodiment was chosen and described in order to best explain the principles of the invention, the practical application, and to enable others of ordinary skill in the art to understand the invention for various embodiments with various modifications as are suited to the particular use contemplated.

The training and the testing data sets for the ANN modules would be generated based on the binary inputs to the logic gates and their corresponding logic outputs. Once the training and testing data sets are generated, the appropriate ANN architecture and associated parameters have to be chosen for particular application. The training and testing data sets are used by the ANN to create stored data sets that are used to detect errors in digital circuits.

The generated data sets are divided into two groups in which the first group consists of data sets used for training and second group consists of data sets used for testing the ANNs. The selection of the training and testing data sets can be made during the ANN training process based on the training accuracies which are the Root Mean Square (RMS) errors.

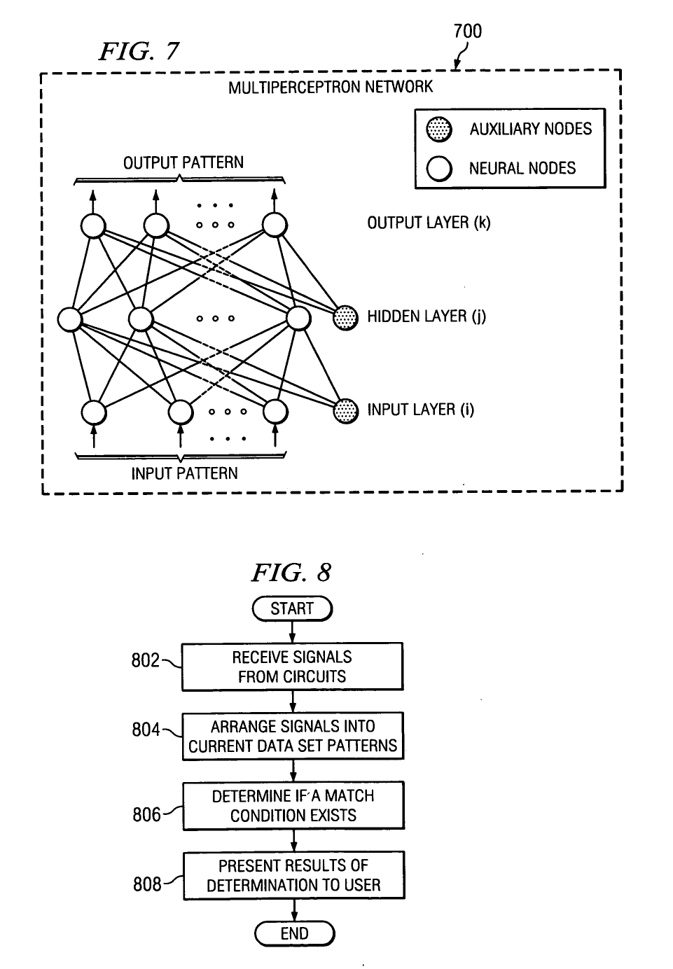

FIG. 7 is a block diagram of a multiperceptron network, in accordance with an exemplary embodiment of the present invention. Multiperceptron network 700 is a three layer multiperceptron network or multilayer feed forward network. In an exemplary embodiment multiperceptron network may be used for training an ANN, such as ANN 500 in FIG. 5, over other multiperceptron networks, as it is known to be well suited for pattern classification, pattern recognition and function approximation. However, in other illustrative embodiments, other multiperceptron networks may be chosen for training an ANN, depending upon the particular implementation.

The connection weights between INPUT LAYER (i) and HIDDEN LAYER (j) is updated using the following equations,
Δwᵢⱼ(n+1)=ηδⱼsᵢ+mΔwᵢⱼ(n)
wᵢⱼ(n+1)=wᵢⱼ(n)+Δwᵢⱼ(n+1)
and the connection weights between HIDDEN LAYER (j) and OUTPUT LAYER (k) are updated using the following equations,
Δwⱼₖ(n+1)=ηδₖsⱼ+MΔWⱼₖ(n)
wⱼₖ(n+1)=wⱼₖ(n)+Δwⱼₖ(n+1)
where n is used to indicate the number of steps in the learning process, η is the learning rate and m is the momentum term.

ANN training is performed by a supervised learning process. The supervised learning process maps over a set of input vectors and the corresponding set of target output vectors where an input vector is presented to the ANN and the actual output of the ANN is compared with the target output. The ANN training process, the design parameters, such as the number of hidden neurons, the learning rate, and the momentum may be varied so as to determine their optimum values. These optimum values are determined based on the most accurate results of the ANN output. The ANNs are trained using a connect prior back-propagation network in which the input layer is fully connected to the hidden layer(s) and output layer(s) until the RMS error in the output between successive iterations is less than or equal to 0.001. The RMS error is used as a convergence criteria to measure the performance of a network during training. Therefore a match condition may exist if the difference between a calculated output and an actual output is 0.001 or less.

The test result is in terms of the absolute error, which is defined as the difference between the ANN output and the target or actual output.

For example:
ANN output(0)−target or actual output(0)=abserror(0−0)=0->no error
ANN output(0)−target or actual output(1)=abserror(0−1)=1->error
ANN output(1)−target or actual output(0)=abserror(1−0)=1->error
ANN output(1)−target or actual output(1)=abserror(1−1)=0->no error

FIG. 8 is a flowchart illustrating the operation of detecting and identifying errors in accordance with an exemplary embodiment of the present invention. The operation begins when signals are received from the circuits (step 802). These signals are arranged into current data set patterns (step 804). In an exemplary embodiment of the present invention, the signals are received and arranged into the current data set patterns by a SCADA system.

The operation determines a match condition exists between the actual output of the current data set patterns and the calculated output of a corresponding stored data set patterns (step 806). In an exemplary embodiment of the present invention, the SCADA system would send the data set patterns, in a binary form, to an ANN for detection of errors. In another exemplary embodiment of the present invention, the ANN is a hierarchical ANN. The ANN would then compare the actual output of the current data set patterns match the calculated output for a corresponding stored data set patterns to see if a match condition exists. If a match condition exists then a zero, or no error, is returned as a result. If a match condition does not exist then a one, or error, is returned. The results are presented in such away that the error or no error result is shown for each digital logic circuit. This allows the user to easily see exactly which digital circuit is causing an error. The results of the determination are presented to a user (step 808) and the process ends.

The present invention thus provides a method, system, and computer program product for detecting and identifying errors in digital circuits. A plurality of inputs are received and organized into a plurality of data set patterns. Each data set pattern is compared to a corresponding stored set pattern. A determination is made as to whether the data set pattern matches the stored set pattern. The results of the comparison are presented to a user for the user to view.

The invention can take the form of an entirely hardware embodiment, an entirely software embodiment or an embodiment containing both hardware and software elements. In a preferred embodiment, the invention is implemented in software, which includes but is not limited to firmware, resident software, microcode, etc.

Furthermore, the invention can take the form of a computer program product accessible from a computer-usable or computer-readable medium providing program code for use by or in connection with a computer or any instruction execution system. For the purposes of this description, a computer-usable or computer readable medium can be any apparatus that can contain, store, communicate, propagate, or transport the program for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk—read only memory (CD-ROM), compact disk—read/write (CD-R/W) and DVD.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers.

Network adapters may also be coupled to the system to enable the data processing system to become coupled to other data processing systems or remote printers or storage devices through intervening private or public networks. Modems, cable modem and Ethernet cards are just a few of the currently available types of network adapters.

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated.

What is claimed is:

1. A computer implemented method for detecting and identifying errors in digital circuits, the method comprising:
receiving a plurality of inputs;
organizing the plurality of inputs to form a plurality of current data set patterns;
comparing an actual data output for each current data set pattern of the plurality of current data set patterns to a calculated data output of a corresponding stored data set pattern of a plurality of stored data set patterns to form a plurality of comparisons; and
determining if a match condition exists for each comparison of the plurality of comparisons to form a plurality of results.

2. The computer implemented method of claim 1, further comprising:
presenting the plurality of results to a user.

3. The computer implemented method of claim 2, wherein presenting the plurality of results to a user comprises a user interface wherein the user interface allows the user to view the plurality of results and control an error detection process.

4. The computer implemented method of claim 1, wherein the steps of receiving the plurality of inputs and organizing the plurality of inputs to form a plurality of current data set patterns is performed by a supervisory control and data acquisition system.

5. The computer implemented method of claim 1, wherein receiving the plurality of inputs comprises receiving a plurality of inputs from digital logic circuits.

6. The computer implemented method of claim 1, wherein the steps of comparing the actual data output for each current data set pattern of the plurality of current data set patterns to the calculated output of the corresponding stored data set pattern of a plurality of stored data set patterns to form a plurality of comparisons and determining if a match condition exists for each comparison of the plurality of comparisons to form a plurality of results are performed by an artificial neural network.

7. The computer implemented method of claim 6, wherein the artificial neural network is a hierarchical artificial neural network.

8. The computer implemented method of claim 6, wherein the artificial neural network is implemented in a real-time environment.

9. The computer implemented method of claim 1, wherein a match condition indicates that an error has not occurred.

10. The computer implemented method of claim 1, wherein the results are in a binary form.

11. A computer program product comprising a computer usable medium including computer usable program code for detecting and identifying errors in digital circuits, said computer program product comprising:
computer usable program code for receiving a plurality of inputs;
computer usable program code for organizing the plurality of inputs to form a plurality of current data set patterns;
computer usable program code for comparing an actual data output for each current data set pattern of the plurality of current data set patterns to a calculated data output of a corresponding stored data set pattern of a plurality of stored data set patterns to form a plurality of comparisons; and
computer usable program code for determining if a match condition exists for each comparison of the plurality of comparisons to form a plurality of results.

12. The computer program product of claim 11, further comprising:
computer usable program code for presenting the plurality of results to a user.

13. The computer program product of claim 12, wherein the computer usable program code for presenting the plurality of results to a user comprises computer usable program code for a user interface wherein the computer usable program code for the user interface allows the user to view the plurality of results and control an error detection process.

14. The computer program product of claim 11, wherein receiving the plurality of inputs and organizing the plurality of inputs to form the plurality of current data set patterns is performed by a supervisory control and data acquisition system.

15. The computer program product of claim 11, wherein receiving the plurality of inputs comprises receiving a plurality of inputs from digital logic circuits.

16. The computer program product of claim 11, wherein comparing the actual data output for each current data set pattern of the plurality of current data set patterns to the calculated output of the corresponding stored data set pattern of a plurality of stored data set patterns to form a plurality of comparisons and determining if a match condition exists for each comparison of the plurality of comparisons to form a plurality of results are performed by an artificial neural network.

17. The computer program product of claim 16, wherein the artificial neural network is a hierarchical artificial neural network.

18. The computer program product of claim 11, wherein a match condition indicates that an error has not occurred.

19. A data processing system for detecting and identifying errors in digital circuits, said data processing comprising:
a storage device, wherein the storage device stores computer usable program code; and
a processor, wherein the processor executes the computer usable program code to organize the plurality of inputs to form a plurality of current data set patterns; compare an actual data output for each current data set pattern of the plurality of current data set patterns to a calculated data output of a corresponding stored data set pattern of a plurality of stored data set patterns to form a plurality of comparisons; and determine if a match condition exists for each comparison of the plurality of comparisons to form a plurality of results.

20. The data processing system of claim 19, wherein the processor further executes the computer usable program code to present the plurality of results to a user.
